(19) United States
(12) Patent Application Publication
(10) Pub. No.: US 2023/0272520 A1
(43) Pub. Date: Aug. 31, 2023

(54) MANUFACTURE AND REFILL OF SPUTTERING TARGETS

(71) Applicant: SOLERAS ADVANCED COATINGS BV, Deinze (BE)

(72) Inventors: Wilmert DE BOSSCHER, Drongen (BE); Ignacio CARETTI GIANGASPRO, Antwerpen (BE); Jai Shankar SUBRAMANIAN, Solon, OH (US); Jeffrey Dieter EDEL, Akron, OH (US)

(21) Appl. No.: 18/016,114

(22) PCT Filed: Jul. 14, 2021
(86) PCT No.: PCT/EP2021/069593

§ 371 Date: Jan. 13, 2023

(30) Foreign Application Priority Data
Jul. 14, 2020 (BE) BE2020/5526

(51) Int. Cl. C23C 14/34; C04B 35/457; C04B 35/495; C23C 4/11; H01J 37/34

(52) U.S. Cl. CPC C23C 14/3414; C04B 35/457; C04B 35/495; C23C 4/11; H01J 37/3426; H01J 37/3491; C04B 2235/3258; C04B 2235/3284; C04B 2235/3286; C04B 2235/3293

(57) ABSTRACT

A method of manufacturing a sputtering target includes the steps of providing a backing structure, providing target material comprising ceramic target material for spraying, subsequently thermal spraying the target material over the backing structure thus providing a target product where at least 40% in mass, for example at least 50% in mass, of the target material including a ceramic target material, and subsequently performing hot isostatic pressing on the target product thus increasing the density of the target material.

### FIELD OF THE INVENTION

The invention relates to the field of sputtering. More specifically it relates to manufacture of sputtering targets, especially targets including ceramic material.

### BACKGROUND OF THE INVENTION

Physical vapor deposition by means of sputtering has become a standard technique to customize the properties of, for example, glass panes or other rigid or flexible materials. ‘Sputtering’ refers to the ballistic ejection of coating material atoms out of a target by means of positively charged ions, — usually argon — that are accelerated by an electric field towards a negatively charged target. The positive ions are formed by electron-ion impact ionization in the low pressure gas phase. The ejected atoms impinge on the substrate to be coated where they form a dense, well adhering coating.

The coating may form layers on the substrate, so the properties of the material (e.g. optical and/or mechanical properties) can be tailored.

Some types of layers are difficult to obtain, for example dielectric layers. For instance, oxidic films are often desired because they can be made with selectable transparency, making them suitable for optical applications such as lenses, filters, and the like. However, deposition of oxidic films is difficult for reasons explained in the following.

It is possible to provide oxide layers by deposition, by sputtering a metal target with a gas mixture including oxygen. This may result in severe hysteresis behavior, which leads to process instability. The relatively high amount of oxygen gas needed to bring the metallic target into the so-called poisoned state to grow a metal oxide layer leads commonly may lead to a drop of sputter rate. The document “OBERSTE-BERGHAUS et al., Film Properties of Zirconium Oxide Top Layers from Rotatable Targets, 2015 Society of Vacuum Coaters, 58th Annual Technical Conference Proceedings, Santa Clara, CA April 25-30, 2015, p. 228-234″ discloses that the use of ceramic targets can alleviate or fully remove the hysteresis behavior, significantly reduce the amount of reactive gas and allow up to three times higher film deposition rates over sputtering processes using metal targets.

For large area applications such as architectural glass, the coatings must be sputtered onto large substrates, and, it is thus required to provide also large targets so that the sputtering is homogeneous. However, large target ceramic pieces are difficult to obtain. Sintering can be used to provide small target pieces that need to be assembled to form a larger sized target assembly, for example as a combination of tiles (for planar targets assemblies) or as stacked sleeves (for cylindrical target assemblies on a cylindrical carrier). These targets are prone to process instabilities e.g. due to arcing especially at their many edges at junctions in the smaller material pieces, as well as different densities in different tiles in practice, which leads to different erosion rates in some tiles. US2012055783A1 discloses thermal spraying over a backing structure to provide a ceramic target, and US2007034500A1 discloses sintering of silicon oxide target by HIP. However, long ceramic sputter targets manufactured by common methods such as sintering or thermal spray often present porosities and a density lower than the theoretical density of the bulk material. In addition, using sintering in order to produce larger material pieces, may require the introduction of organic bonding agents, impacting the purity of the resulting target material. This is even more significant in the case of materials that decompose thermally or sublimate at the manufacturing pressures and temperatures employed. The lower density and porosity are linked to a negative performance during sputtering due to reduced thermal conductivities, material spitting, dust formation and subsequent increased arcing rates. JP2013147368A discloses the possibility of obtaining a long ceramic cylindrical target material prepared by cold isostatic pressing (CIP) of specially prepared granules, followed by sintering. Similarly, JP2018009251A discloses a cylindrical molded product for a target prepared by CIP followed by sintering. However, it is necessary to join the target material to a backing tube with soldering or brazing material as adhesive, which requires extra steps.

### SUMMARY OF THE INVENTION

It is an object of embodiments of the present invention to provide a method of manufacturing a target which provides a high density and comprises ceramic target material, and a target for sputtering obtained by such method, with the possibility of reduced number of separate pieces in a target assembly, or even having a single piece target.

It is an advantage that targets with high density can be provided, for example with low porosity and large size. It is an advantage that little assembly is required to manufacture a target, as the number of tiles or segments can be reduced. It is an advantage that single one-piece targets can be provided, with no need to assemble tiles. Single piece, large size, and high density targets may exhibit advantageous behavior during operation; e.g. having higher process stability or allowing a higher sputter power density and thus a higher deposition rate.

In some embodiments, the method of manufacturing comprises refilling a target.

In a first aspect the present invention provides a method of manufacturing a sputtering target comprising the step of providing a backing structure, providing ceramic target material for spraying, subsequently thermal-spraying the target material over the backing structure. The method is adapted to provide a target product where at least 40% in mass, for example at least 50% in mass, of the target material comprises ceramic target material. Subsequently hot isostatic pressing is performed on the target product, thus increasing the density of the target material.

It is an advantage of embodiments of the present invention that a dense target can be provided from a starting sprayed target, allowing providing pieces of similar shape and size as the backing structure; for example they may be pieces with a dimension of 400 mm or larger, e.g. 600 mm, such as 800 mm or larger. Advantageously, a single backing structure may be used. Alternatively a target assembly can be provided which combines several backing structures, being assembled to a larger target with smaller tiles or segments than in existing similar targets. and reducing or avoiding presence of dust or pores in the target.

In some embodiments, performing hot isostatic pressing comprises performing isostatic pressing without a canister, advantageously avoiding fitting the sprayed target product, and not requiring to produce custom canisters with dimensions adapted to the sprayed product.

In some embodiments, providing ceramic target material comprises providing volatile material. This volatile material shows, at pressures close to atmospheric pressure, either a sublimation point temperature (or sublimation temperature, in short), or a melting point temperature (or melting temperature, in short) and an absolute boiling point or decomposition temperature (or boiling temperature, in short) being less than 30% higher, or being lower, than its melting temperature in degrees Celsius.

It is an advantage of embodiments of the present invention that materials which decompose easily or sublimate (e.g. indium oxides, tin oxides, zinc oxides, tungsten oxides) can still provide a target with a density close to the theoretical density of the starting material, while allowing a great freedom and reduced fragility and without other drawbacks of sintering.

In some embodiments, the volatile material comprises at least 60% in mass, for example at least 70% in mass or at least 80% in mass or at least 90% in mass, of the total target material. Most of the target may be volatile material such as oxides.

In some embodiments, providing a sprayed target product comprises providing a target product with a density lower than 90%, for example lower than 85%, for example lower than 80%, of the theoretical density of the material. Performing hot isostatic pressing comprises increasing the target density by at least 5%, for example at least 10%, for example at least 15%, for example at least 20%, of its theoretical density, optionally obtaining an overall target material density of at least 90%, for example at least 95%, or at least 98%, or at least 99% of its theoretical density.

It is an advantage of embodiments of the present invention that these materials that decompose or sublimate easily can be provided with a highly effective thermal-spraying at a relatively low temperature and low density of the sprayed target, as the subsequent HIP process increases the target density, e.g. to a density of at least 90%, for example at least 95%, or at least 98%, or at least 99% of the theoretical density.

In some embodiments, the method is adapted to provide a densified ceramic target material having a resistivity lower than 1000 Ohm.cm.

It is an advantage that the method can be used to manufacture targets having sufficient conductivity to be sputtered with DC or MF AC power modes, thus not requiring RF (> 1 MHz) signals as being typically used for insulating materials.

In some embodiments, providing a backing structure comprises providing a conductive mold including a groove adapted to overlap the sputter racetrack. Thermal-spraying is performed by thermal spraying a large quantity of material at the areas within the groove and a small quantity on areas outside the groove. Optionally, providing a conductive mold including a groove comprises providing an eroded target, so the method of manufacturing a sputtering target comprises refilling and recover the eroded target. Optionally, providing a backing structure comprises providing a tubular backing structure, e.g. a cylindrical backing structure, e.g. a shaped tubular backing structure with grooves at its ends as in the mold.

It is an advantage of embodiments of the present invention that the thermal spraying allows saving material by providing more material over the places where most of the erosion takes place while providing less material anywhere else. It is an advantage of embodiments of the present invention that an eroded target can be recovered with a dense material, even if the eroded target was not as dense. It is a further advantage that the spraying technique allows control of deposition profile for providing material in accordance with the level or erosion of the target.

It is an advantage of embodiments of the present invention that tubular targets can be provided.

In some embodiments, the method comprises coating the surface of the sprayed target with a capping layer of material with a lower porosity than the sprayed target before performing hot isostatic pressing, for removing surface pores.

It is an advantage of embodiments of the present invention that the density of sprayed targets with open pores on the surface can be increased. It is a further advantage that the capping layer has better fitting than a traditional HIP canister. It is a further advantage that the capping layer can follow the surface topography of the sprayed target without the need of custom designed enclosure or canister, e.g. it may be a binding layer applied from the liquid phase or a sprayed layer with material from the solid phase (e.g. wire, powder, ...)

Optionally, coating the surface with a capping layer of material is performed with material comprising or consisting of the same material as the sprayed target at higher density than the sprayed target.

It is an advantage of embodiments of the present invention that there are less shrinkage differences between the capping and underlaying material, and less problems of poisoning the target material. It is a further advantage that the sprayed target can be provided in a highly efficient thermal process with little material loss, and the capping layer can be provided with a configuration which optimizes the density, while the relative reduction of efficiency is less substantial as the higher density is only needed on the thin capping layer.

In some embodiments, the capping layer is provided by spraying, for example cold or thermal spraying.

It is an advantage of embodiments of the present invention that the capping layer has low mass, thus reducing the loss of material during production, and it may be easier to shrink with the target material.

In some embodiments, the method comprises polishing the surface of the sprayed target before performing hot isostatic pressing.

It is an advantage of embodiments of the present invention that surface pores can be closed via polishing in some materials, allowing provision of a thinner capping layer, or even making the capping step optional.

In some embodiments, the method further comprises partially or completely removing the outer layer of the target after performing hot isostatic pressing.

It is an advantage of embodiments of the present invention that surface can be prepared and contamination, dust or irregularity can removed before use.

In some embodiments, the method further comprises providing a bonding layer on the backing structure before spraying the target material over the backing structure, wherein the bonding layer has a thickness of 500 micrometers or less. In embodiments of the present invention, the bonding layer may be provided by thermal spraying.

In a second aspect, the present invention provides a sputtering target comprising a single piece comprising ceramic material for sputtering, wherein the absolute boiling or decomposition temperature of said material is less than 30% higher than its melting temperature or decomposing before melting, or having a sublimation temperature, and having a material density of at least 90%, for example at least 95%, for example at least 98% of its theoretical density. The temperatures may be defined for example at the same ranges of pressure as the working pressure of thermal spraying process

It is an advantage of embodiments of the present invention that a dense target can be provided as a single large piece, with no need to provide the target as a combination of smaller target tiles or segments. It is a further advantage that target material be used to produce the target with spraying instead of sintering, even if the material tends to decompose at high temperatures with reduced melting. It is an advantage of embodiments of the present invention that a high density target can be provided, with very low porosity.

In some embodiments, the single piece has a length of at least 600 mm, e.g. at least 800 mm. It is an advantage of embodiments of the present invention that large substrates can be homogeneously sputtered.

In some embodiments, the ceramic material for sputtering comprises any of indium tin oxide, ZnO, or SnO₂, or In₂O₃, or WO₃ or any combination thereof.

It is an advantage of embodiments of the present invention that a ceramic target material with low porosity can be provided with no need of sintering dust.

In some embodiments of the present invention, the sputtering target comprises a backing structure and bonding layer between the backing structure and the ceramic material for sputtering. The bonding layer has a thickness of 500 micrometers or less, for instance 300 micrometers or less, for example 250 microns or less, or 150 microns or less, for example around 100 microns. It is an advantage of embodiments of the present invention that the bonding layer improves attachment of the ceramic material to the backing structure.

The target of embodiments of the second aspect of the present invention may be provided in accordance with embodiments of the method of the first aspect, thereby obtaining a thermally spraying, hot isostatic-pressed target.Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates a tubular target product in a hot isostatic pressure vessel in a manufacture step in accordance with embodiments of the present invention

FIG. 2 is a flowchart of the method of the present invention for manufacturing targets.

FIG. 3 illustrates a planar target assembly formed by four pieces in accordance with embodiments of the present invention.

FIG. 4 illustrates a perspective view of a mold or backing structure for providing a target in accordance with embodiments of the present invention.

FIG. 5 illustrates the cross section of a mold and the procedure steps to provide a target in accordance with embodiments of the present invention.

FIG. 6 illustrates a cross section of a tubular target product for providing a tubular target in accordance with embodiments of the present invention.

FIG. 7 illustrates a cross section of a tubular target product for providing a tubular target and refilling a used target, in accordance with embodiments of the present invention.

FIG. 8 illustrates a cross section of a tubular target in accordance with embodiments of the present invention.

FIG. 9 illustrates a cross section of a tubular target in accordance with embodiments of the present invention.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The dimensions and the relative dimensions do not correspond to actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. Thus, the scope of the expression “a device comprising means A and B” should not be interpreted as being limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to “backing structure”, reference is made to the structure on which target material for sputtering is provided. The backing structure holds the target material and can be attached to a sputter source in a coating chamber. For example, the backing structure may have a circular or rectangular area over which the target material is provided, as in the so-called “planar targets”. Backing structures do not need to be flat. They may be molded to provide grooves. Targets with tube-like, e.g. cylindrical, backing structure are known as “tubular targets”. A backing structure may comprise a carrier. It may include a carrier and an extra layer for providing or improving adhesion between the target material and the carrier. In some embodiments, a backing structure may include a carrier and target material, for example the backing structure may be an eroded target over which new target material is provided, in accordance with embodiments of the present invention.

While metals can be cast, molded, extruded or formed into targets, some materials prove difficult to process in order to manufacture a target from them. Oxidic materials are a typical example, although the present invention is not limited to oxidic target material, and other ceramics can be used. Compression and heating of powdered material provide coalescence into targets, in a process known as sintering. However, it is difficult to provide single-piece targets via sintering, for example large targets. In some cases density is not optimal, and the materials may present porosity; density is usually not homogeneous, and shrinkage and even crack formation may occur. Sintering can be used to provide for example target tiles with dimensions of e.g. 134.53 mm × 145.05 mm or smaller. It is much easier to provide these small pieces by sintering, which have homogeneous composition and density, and may attain high density, almost theoretical density. These small pieces, e.g. tiles or sleeves (cylindrical segments), can be used to assemble a large target (target assembly). However, this approach presents several drawbacks. First, mounting the pieces should be done with controlled spacing over an appropriate backing tube/plate (e.g. with compatible coefficient of thermal expansion). Bonding material should be provided and activated between the pieces and the backing structure (e.g. by melting of indium). In preferred instances, this bonding material should be conductive, for generating a conductive path. These issues are not limited to the manufacture of the target, as the assembled target may give troubles during its use. As the target is made of smaller pieces, the surface usually presents seams or edges between the smaller pieces. These edges are prone to arcing during sputtering, where a very high electrical field forms around the edge. Edges may be also more sensitive to defect formation (e.g. nodules, dust, ...). These nodules may have dielectric character and locally reduce the conductivity of the target surface. Also, the maximum achievable power level is often limited by the bonding material and quality of the bonding, and not by the target material itself. In some cases, binding compounds such as organic compounds are mixed in the target material to improve the integrity, but these result in contamination of the final target, which turns into contamination on the sputtered material on the substrate during use.

Moreover, due to manufacturing issues, not all pieces have exactly the same properties and performance, which affects the overall performance of the target. For example, this means that the pieces may be eroded during sputtering in an inhomogeneous way, so sputtering has to be stopped before the thinnest segment is fully consumed (retaining some intrinsic mechanical strength) and reducing target utilization. For example, although the pieces are supposed to have the same density, some pieces may have a deviating density and be more sensitive to arcing, powder or nodule formation, or potentially generating defects.

Additional problems raise for tubular shaped targets, namely:
Hard to guarantee good circumferential bonding
Bonding material may appear at the target surface through the gap between two segments (risk of contaminated sputtering)
Often need for expensive backing tube (e.g. titanium instead of stainless steel, requiring higher level of straightness and roundness, etc.)
Narrow tolerances on the inner diameter of the sleeve and outer diameter of the backing tube.

To overcome these issues, other techniques have been attempted to provide targets made of fewer pieces, e.g. of a single piece and having relatively large dimensions. One of these techniques is thermal spraying of material directly on a large backing structure.

Spraying is a proven technology for making larger size sputter targets, which can be implemented for several target geometries; e.g. cylindrical or flat targets. It is inherently related to the technology. Quite dense material layers can be generated. While for example cold spraying may rely on the plastic deformation of the source material (e.g. metals or metal alloys and compounds), thermal spraying acts on the melting of the source material.

Hence, thermal spraying allows realizing larger sized single piece targets with high density (e.g. typically more than 85%, more than 90%, even more than 95%) for most metallic materials (pure, alloyed, ...) and even for some ceramic materials.

However, as thermal spraying requires the formation of droplets by partial and/or total melting of the projected material, it is challenging to provide coatings from materials that present difficult melting (e.g. high melting point temperature plus low thermal conductivity) or thermal stability issues. Some materials significantly decompose and/or sublimate at the spraying conditions resulting in substantial fume and dust formation. As a result, it is often difficult to achieve high-density coatings and hence it is difficult to manufacture a target comprising these materials. Targets obtained from these materials present a density lower than 90%, even lower than 80%, of the theoretic density. Usually these materials are ceramics, e.g. comprising oxides, although the present invention is not limited to oxides.

Targets with a density lower than the theoretical density have relatively more surface bonds relative to bulk bonds, requiring lower energy to provide sputtering effect, so for a given energy density, more target atoms can be dislodged. This manifests as a higher sputter rate for given power level. However, low density also increases the porosity of the target. Pores may act as defect sites during an abnormal glow discharge, increasing the probability of arc events. Additionally, the surface is rougher and the electrical field distribution may be less uniform. Moreover, porosities may break open during the sputter removal process and release a pocket of gas, eject material, or bring a spot of different composition to the surface (e.g. having another secondary electron emission yield). Low density targets are also more susceptible to be contaminated by dust. For example, in the case of targets made by thermal spraying, high amounts of fine dust can be trapped between splat contacts and/or porosities.

For some of these materials having lower density and, possibly, trapped dust, it has been observed that under specific sputtering conditions, insulating islands or particles form on the surface. For example nodules may form with increased resistance. Dust may also form and accumulate over time (hours or days) on the target surface and eventually may lead to increasing arcing rate and, as a consequence, unstable sputtering.

The present invention provides a method of manufacturing highly dense sputtering targets, regardless of the type of ceramic material used. By sintering, the size of tiles or of segments of a tubular target is limited.

In embodiments of the present invention, sintering is not used but thermal spraying, so large target pieces, e.g. a single-piece target, or targets with a dimension as large as at least half of the dimension of backing structure can be provided without the need for introducing impurities that may act as bonding agent within the target material. In some embodiments the targets may have a side length or axial length at least 600 mm or at least 800 mm, e.g. at least 1 m, e.g. more than 2 m, for example 4 m.

The invention provides densification of up to 20% increase of the density of the ceramic target material, for example at least 90%. This is densification is performed by hot isostatic pressure (HIP) process of the target product obtained from the thermally sprayed target.

In a first aspect, the present invention provides a method of manufacturing a sputtering target. The method includes thermally spraying of target material comprising a fraction of ceramic material on a backing structure, thereby obtaining a sprayed target. A target product is provided. The target product is then submitted to hot isostatic pressure (HIP), so the material on the target product is densified. The pressures can range from 10 MPa to higher than 200 MPa, at temperatures of hundreds of degrees, for example higher than 700 K, for example higher than 1000 K and extending beyond 1300 K, such as 1600 K. HIP is usually done in a special pressure chamber, and it can be done on objects with the suitable size.

In particular embodiments, the sprayed material comprises ceramic volatile material. These materials can be defined as materials which thermally decompose or sublimate at temperatures in the range or surpassing the melting point, e.g. being typical temperatures of thermal spraying. In particular, volatile material presents a sublimation or a decomposition temperature, and/or has a melting point temperature close to the boiling point temperature, for example the boiling and/or decomposition temperature being less than 30% higher than the melting point temperature in degrees Celsius (e.g. being lower than the melting point). The target material of the present invention comprises at least one volatile material. In some embodiments, the boiling or decomposition temperature of the volatile material may be less than 25%, or less than 20%, or less than 15% higher than the melting temperature. Decomposition of the volatile material may even occur at temperatures lower than the melting point. It is noted that these temperatures are provided at pressures typically used in thermal spray processing. For example, these temperatures and temperature ranges are defined at atmospheric pressure. For example, these temperatures and temperature ranges may be defined at pressures between 700 and 1300 hPa.

A large part of these materials decomposes due to the high temperatures required for the thermal spraying. This results in a sprayed product with low density and porosity. In particular, thermal spraying of volatile materials often results in insufficient melting and/or evaporation/sublimation of the material and severe dust formation. The incorporation of unmolten particles and/or dust into the sprayed coating negatively affects the contact between splats of the projected material of the sprayed target, with a subsequent density decrease and porosity increase. Even if the surface is treated to fill pores, the target product has internal pores which are revealed due to the erosion of the sputtering process, and cause problems during sputtering such as dust, deposits, arcing and ultimately unstable sputtering and defect formation in the sputter deposited layer.

In particular, sprayed targets comprising at least 40% of volatile materials may have lower density and often include pores, voids and/or inclusions such as dust on its surface and/or in the matrix, etc. These temperatures are defined in the range of pressures as the pressure present during spraying. Usually, thermal spraying submits the material to be sprayed at temperatures in the range or preferably surpassing the melting point. Best thermally sprayed coating properties may be achieved when the fed material (typically wire or powder) is getting fully molten and is projected to the backing structure as droplets, where they solidify in a splat like structure. These materials with melting point temperature close to the boiling point, and/or decomposition or sublimation, may be hard or virtually impossible to be thermally sprayed.. It is not fully clear why sublimating materials can still be sprayed in some cases, but it is believed that strong drag from the flame, combined with superheating and out-of-equilibrium melting plays a role. It is also believed that other materials that can melt, but start decomposing before reaching the melting point (such as ITO), may still be sprayed thanks to superfast heating during spraying. However, this process results in severe feedstock decomposition, fumes and dust during thermal spraying. Hence, the sprayed target will have low density, porosity (voids or other components) and such, which give troubles during sputtering. As a comparison, materials such as titanium dioxide and zirconium dioxide can be provided in coatings with high density, close to the theoretical density (e.g. > 95% for titanium dioxide TiOx and > 92% for zirconium oxide ZrOx). These materials melt without thermally decomposing and at much lower temperature than their boiling point. They do not present sublimation and show well defined melting and boiling point temperatures at atmospheric pressure, which is usually the pressure present during spraying.

The following table shows the density of some thermally sprayed targets vs the density of the bulk material and the percentage of this bulk density that the sprayed material achieves.

TABLE I

Bulk theoretical density vs measured density, and porosity

| | Bulk material | Target measurement | | Relative density |
|---|---|---|---|---|
| | Density (g/cm³) | Density (g/cm³) | Porosity | |
| AZO (2% Al) | 5.56 | 4.68 | 7.3% | 84.2% |
| ITO (10% Sn) | 7.14 | 5.56 | 15.8% | 78.4% |
| TiOx | 4.23 | 4.13 | 1.6% | 97.6% |
| ZrOx | 5.68 | 5.29 | 6.0% | 93.2% |

Clearly, ITO has a lower relative density and a higher porosity level than for example titanium or zirconium oxide. Aluminium-doped zinc oxide shows a reduction of relative density to values close to 85%.

The present method provides a step of densification in order to form a target for stable sputtering. This method comprises submitting the target product, e.g. the sprayed target or the sprayed target after a surface preparation, to hot isostatic pressing (HIP) thereby obtaining a pressed or densified target. Where in embodiments of the present invention reference is made to “target product”, reference is made to a target before the HIP process. The target product may be a sprayed target as such, in other words, a target obtained by thermal spraying which can be submitted to a HIP process without further preparation, or it may be a sprayed target after a further preparation of the surface, before the HIP process. After the HIP process, a densified target, also referred to as dense target, or simply target, is obtained.

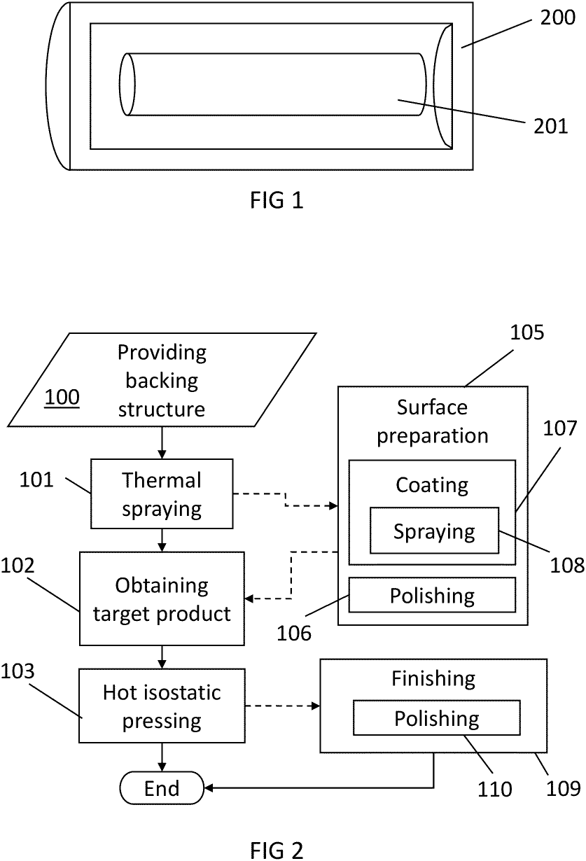

Hot isostatic pressing (HIP) process is a manufacturing process used to reduce the porosity and increase the density of metals and many ceramic materials. This improves the material’s mechanical properties and workability. The HIP process subjects a component to both elevated temperature and isostatic gas pressure in a high pressure containment vessel. FIG. 1 shows an exemplary vessel 200 which provides the required temperature and pressure to a tubular target product 201 after thermal spraying. The pressurizing gas most widely used is argon. An inert gas is preferred to reduce chemical reaction of the material with its surrounding environment. The chamber is heated, causing the pressure inside the vessel to increase. Many systems use associated gas pumping to achieve the necessary pressure level. Pressure is applied to the material from all directions (hence the term “isostatic”).

The process is well known for metal castings from metal powders. The inert gas is applied between 50.7 MPa to 310 MPa, commonly 100 MPa. Process soak temperatures range from 482° C. (Al castings) to 1320° C. (Ni-based superalloys). The simultaneous application of heat and pressure eliminates internal voids and micro-porosity through a combination of plastic deformation, creep, and diffusion bonding, with improving fatigue resistance of the component. Primary applications are the reduction of micro-shrinkage, consolidation of powder metals, and metal cladding. The process can be also applied to ceramic composites, which gives similar results, albeit adapting the pressures and temperatures.

Thus, the HIP process can be applied to the target product of embodiments of the present invention to densify it. In some embodiments, the HIP process increases the density of the target material by at least 5%, for example at least 10% or 15%, for example at least 20% of the theoretical density. Thus, the pressed target will have a density of at least 90% of the theoretical density, for example 95% or 98% or 99% or even higher. Such target may in principle be used for sputtering. However, other intermediate and/or finishing steps can be provided.

The resulting target will have a very high purity where 99.9% of the material is intended for sputtering, with very low contamination, because no binding agent may be required in the target material, as it is the case of some sintering methods.

FIG. 2 shows a flowchart with exemplary steps to manufacture a sputtering target in accordance with embodiments of the present invention.

First, a backing structure is provided 100. This may comprise providing a carrier to form a planar or tubular target. It may comprise providing a mold, e.g. a planar mold or tubular mold or the like; for example providing a mold with grooves where the high erosion (e.g. erosion from the plasma racetrack) is expected. In some embodiments, providing a backing structure comprises providing a metal structure, e.g. a metal carrier. For example it may be an inexpensive structure, e.g. stainless steel. It may be a structure comprising material which present a strength against the HIP conditions. For example, it may comprise titanium. In some embodiments, the backing structure comprises material with a compatible thermal expansion coefficient. In some embodiments, providing 100 a backing structure comprises providing a bonding layer for better and more controlled adhesion of the target material, e.g. onto a carrier such as a mold, backing tube, etc. Furthermore, a bonding layer may be chosen to be sufficiently thick and having mechanical and thermal properties to buffer differences between the backing structure and the deposited target material. For example, the bonding layer may have a TEC being between the TEC of the backing structure and of the sprayed target material. This may be especially important for maintaining good adhesion after performing the HIP cycle.

The optional bonding layer on the backing structure may be provided by spraying, before providing the material for sputtering, e.g. before spraying and densifying the material for sputtering. Providing the bonding layer may comprise providing material with a high melting temperature in sprayable form, and spraying it onto the backing structure. A thin bonding layer, for example a layer of 500 microns or less, for example 300 microns or less, for example 250 microns, or 150 microns or less, for example around 100 microns, may be provided. For example, the material may have melting temperature of at least 500° C., for example at least 900° C., for example at least 1000° C. In some embodiments, the material may comprise titanium, nickel, nickel-aluminum alloys, copper, or a mixture thereof.

The high melting temperature ensures that the bonding will occur at least during the subsequent spraying of material to form the sprayed product. In some cases, in the end product, the bonding material will be present as a layer between the backing structure and the densified material, after the HIP process, thanks to the relatively high melting temperature of the bonding material. In alternative cases, the material may diffuse between the material of the backing structure and/or the material for sputtering, forming a composition gradient rather than a layer, further improving bonding between the material for sputtering and the backing structure.

However, the method of the present invention is not limited to the use of a bonding layer, and target material can be directly sprayed on the bare backing structure material for providing the sprayed product, before HIP.

In some embodiments, providing 100 a backing structure may comprise providing a single piece backing structure for providing a target piece of at least 600 mm, e.g. at least 800 mm, for example 1 m, or 2 m, or 4 m or more, for example a tube of 800 mm or more, thus allowing the provision of a single piece large target for sputtering large areas, such as glass panes or the like.

In some embodiments, providing a backing structure comprises providing a used target, e.g. comprising a carrier and remaining uneroded material, where the grooves are actual erosion grooves generated by a plasma racetrack during previous sputtering of the target. Thus, the present method of manufacture targets may be used to restore targets with highly dense target material, with a density close to theoretical density (density of the bulk material), where the target material comprises volatile ceramic material.

The target material is applied 101 to the backing structure by thermal spraying so as to obtain a sprayed target. For example, the fraction of ceramic material itself can be thermally sprayed. Thermally spraying 101 target material may comprise plasma spraying, flame spraying, high velocity oxygen fuel spraying, or any other technique.

In some embodiments, applying 101 target material comprises thermally spraying volatile material thus obtaining a sprayed target which includes at least 60%, for example at least 70% of this volatile material, such as ZnO, In₂O₃, SnO₂, WO₃, or mixtures or compounds thereof, e.g. SnO₂ and In₂O₃; e.g. ITO comprises typically at least 80 wt % of In₂O₃ and less than 20 wt.% of SnO₂; for example in a 90:10 composition ratio. Other mixtures or compounds include tin oxide and indium, tin oxide and indium oxide, ITO and metallic tin. Some examples are given in paragraphs [0018], [0019], [0025] of patent EP2294241B1.

It is noted that SnO₂ sublimates at 1800° C.-1900° C. while the melting point is 1630° C., so the sublimation takes place at temperatures between 9.5% and 14.3% higher than the melting temperature. ZnO decomposes by sublimation at 1974° C., so the melting and boiling temperatures are considered the same (0% difference). In₂O₃ decomposes below 2000° C. while the melting point is 1910° C., so decomposition takes place at a temperature 4.5% higher than the melting point temperature. WO₃ shows a boiling point temperature at 1700° C. while the melting point is 1473° C., so the boiling temperature is around 13.3% higher than the melting temperature, although some sources indicate that tungsten oxide may sublimate below 750° C., between 200° C. and 1100° C., which is lower than the melting temperature. Indium tin oxide, depending on the exact composition, starts decomposing at around 900° C., while the melting temperature is typically considered higher, at around 1526-1926° C. Some conflicting data can be found in the literature regarding the above indicated threshold temperatures for these materials depending, among other factors, on oxygen partial pressure and humidity content.

As explained earlier, some of these materials can still be sprayed However, the sprayed material usually brings gas and dust to the target material due to the decomposition and/or sublimation. It is believed that decomposition and/or sublimation of the sprayed material causes these problems.

In embodiments of the present invention, providing 101 target material by thermally spraying a backing structure comprises spraying the same material as the material forming the backing structure. The issue with TEC compatibility is thus mitigated. For example, the method of manufacturing a target may comprise refilling the target by thermally spraying the same material on the eroded target (the eroded target being the backing structure).

From the sprayed target, a target product can be obtained 102. For example this target product may be a single piece with a dimension, e.g. a length, of 600 mm or more; e.g. 800 mm or more. In some embodiments, the sprayed target itself may be the target product which can be then submitted 103 to hot isostatic pressing (HIP). For example, if the initial density of the as-sprayed material is sufficiently high and/or does not contain open pores, the sprayed target may be placed in the HIP vessel “as is”.

In alternative embodiments, the sprayed target is submitted 105 to a further preparation step, mainly a surface preparation, thereby obtaining a target product made of a single piece comprising target material. For example, this intermediate preparation step can be carried out if full densification cannot be achieved from the sprayed target “as is”; e.g. due to the presence of open pores.

For example, the intermediate step may comprise closing the surface open pores by grinding and/or polishing 106 the target. Polishing the target results in a smooth surface with a characteristic shine, which indicates that roughness is being reduced and that the density of open pores may be reduced as well.

Additionally or alternatively, the intermediate step may comprise coating 107 the surface of the sprayed target with a coating adapted to close the open pores, e.g. providing few layers of material so that surface pores close. In embodiments of the present invention, the pores are covered and closed, rather than infiltrated. Filling of the pores is less desired, because once they are filled the hot isostatic pressure processing cannot close them, and the density and homogeneity thereof is less controllable and it may be negatively affected. Infiltration of the pores may result in contamination of the target material with infiltrating material over a significant depth and it is not a desired situation. For example, layers of a thickness of 2 mm or less, e.g. 1 mm or less can be used, for example 500 µm or less, e.g. 300 µm or even thinner, e.g. 100 µm. This intermediate coating step can be done using an overlay material. The coating can be provided homogenously over the target material so the coating has a uniform thickness. In some embodiments, coating can be done by spraying 108, e.g. thermally spraying. However, the present invention is not limited to thermally spraying, and the further coating can be done by cold spraying, sputtering, vapor deposition, and any other technique compatible with the subsequent HIP process, and preferably which allows closing the surface pores instead of filling them with the overlay material. Preferably, the coating does not cause degassing during HIP, advantageously providing a safe HIP process with less contamination to the vessel 200 (FIG. 1).

In some embodiments, the overlay material is a material different from the target material. For example, the overlay material may be a metal, e.g. a metal with a high melting point, such as higher than at least 20% higher than the maximum temperature attained during the HIP cycle, for example at least 30% higher, for example as stainless steel (which is relatively inexpensive) or titanium (which presents good strength under the HIP conditions submitted to the target thereafter) or nickel, or a metal alloy with sufficiently high melting point. However, the present invention is not limited to metals.

In some embodiments, the overlay material may be the same as the target material. This has the advantage that, after HIP, there is no need to remove the overlay material. For example, the overlay material may be provided also by spraying, e.g. thermal spraying, however spraying under different conditions that optimize densification over effective spraying (e.g. obtaining a high deposit efficiency) thus providing a capping layer with lower porosity than the underlaying target material. This has the advantage that the setup does not need to be changed, e.g. the sprayed target does not need to be removed from the spraying chamber, only the spraying parameters need to be changed. It has also the advantage that there are no issues of incompatibility of expansion coefficients, as both materials are the same, thus reducing cracks or issues of shrinkage during the HIP process.

In an illustrative example, ITO can be provided with different spraying conditions. The material used to provide ITO targets is expensive. Usually, spraying conditions (plasma, temperature, feeding rate) are optimized to waste as little material as possible through the ventilation of the spraying chamber. However, it is possible to tune the spraying conditions to improve the density so as to obtain a surface with low porosity, at the expense of higher quantity of wasted material. The present invention allows providing most of the target under conditions that save material (resulting in a suboptimal density), with a final step of providing few layers, for example up to half millimeter, one or two millimeters at the surface, under conditions that maximize density. Material is wasted at a higher rate but for a very limited time.

Thus, from the sprayed target, a target product can be obtained by preparing 105 the surface of the sprayed target. The HIP can be performed directly on the target product.

The present invention provides HIP with no canister. A canister preferably needs to tightly fit the target product allowing optimal densification. By contrast, coating is provided directly on the surface, while a canister needs to be custom-designed to adapt to the surface topography. A canister also usually requires welding to the sprayed target and evacuating to vacuum, thus reducing contamination. Besides, it can bring problems of shrinkage. The mass used is larger than with coating, so it gives more shrinkage issues than a thin coating. In some embodiments of this invention the HIP process is performed directly on the target product, so the target product without canister is introduced in the vessel 200.

Performing 103 a HIP cycle may comprise submitting the target product to very high pressures under well controlled heating, with ramp up, steady state and cooling profiles. The pressure may be e.g. 10 MPa or higher, e.g. at 50 MPa, 100 MPa, or over 200 MPa, or any value in between. The heating may be done e.g. up to 600 K, preferably hotter, e.g. up to 1000 K, or up to 1400 K or even higher, e.g. over 1800 K, or any value in between. The particular values of pressure and temperature depend on the material used. Typically, the temperatures need to be higher than for metals.

The HIP cycle is introduced for densifying the target material in order to achieve the advantages of a thermal sprayed target and of a sintered target. Thus, a single piece target of constant composition across the target can be provided, with no need for additional bonding (which may limit the maximum achievable power during sputtering). There is no need of presence of gaps over the target which would cause defects and arcing because the target may be provided as a single piece. Artifacts which typically appear on low density targets are reduced or avoided. These artifacts include e.g. nodule or dust formation, which lead to arcing and unstable processes, potentially giving defects in the deposited sputter coating.

The sputter target material can be densified to densities of at least 95%, for example denser than 97%, or than 98%, even denser than 99% of the theoretical density of the material (of the bulk material).

The HIP cycle can be designed and adapted to optimize some aspects of the densified target, while sustaining the integrity of the target. The densification allows reaching densities close to the theoretical density. Internal pores can be eliminated, which provide a smooth erosion profile and homogeneous sputtering for longer. Mechanical properties are also improved (improved ductility and/or resistance to fatigue or impact). The HIP process also improves bonding of the target material to the backing structure, e.g. bonding by diffusion to the backing structure. HIP may also contribute to stress relaxation of the sprayed layer.

The design and adaptation of the HIP process includes temperature, pressure, as well as pressure profile and temperature profile during the HIP cycle (e.g. rate of heating/reheating, cooling, pressurization, etc.).

In some embodiments, the densified target can be readily used for sputtering. In alternative embodiments, the surface of the densified target may be optionally submitted 109 to a further treatment, thus finishing the target after the HIP process.

Removal of any contamination that may be induced by applying a capping layer, possibly containing undesired elements, can be done by submitting 109 the target to the finishing step, for example grinding and/or polishing 110, although other steps such as chemical treatment or the like can be used. Moreover, after performing the HIP process even if not using a capping layer, directly on the sprayed (and optionally polished) target, the top morphology of the target material (material closest to the surface) may deviate from its bulk properties. This part may advantageously be removed. For example, performing the HIP cycle without the capping layer may retain some porosity at the top (open pores with limited extent into the material), while deeper voids were originally already closed pores and became densified.

For example, the further treatment may comprise removing the overlaying protective layer. If a coating with material different from the target material is used, finishing the process may include removing from the target the first layers including the coating material.

In some embodiments, a dense target with at least one dimension being at least 600 mm, e.g. 800 mm can be obtained (e.g. an axial length for a tubular target, a side or a diagonal of a rectangular or square target), for example a single target as large as the backing structure, seamless and in one piece, or at least with very few tiles in large planar targets where at least one piece has a dimension which is more than 50%, for example being as large as, one dimension of the backing structure of the whole target. The density can be 90% or higher, e.g. 95% or higher, even if volatile materials are used as target material, e.g. more than 60% or 70%, e.g. more than 80% or even at least 90% of the target material is a volatile ceramic material.

The resulting target may be highly pure, e.g. with 99.9% of target material intended for sputtering. No other material, such as binding compounds, needs to be included in the target material, as it is the case with sintered targets, so no residue is left.

The target may be preferably conductive, so sputtering at frequencies lower than RF can be provided. For example, it may include conductive material. For example, the target may have a resistivity of 1000 Ohm.cm or less, preferably below 100 Ohm.cm, more preferably below 10 Ohm.cm, even lower than 1 Ohm.cm. It is an advantage of embodiments of the present invention that the target presents a conductivity high enough so that it can be used with lower frequency AC sputtering process (e.g. below 200 kHz, such as 70 kHz or lower, e.g. 30 kHz or lower), or even DC sputtering process, suitable for providing optical coatings. The resistivity can be measured by any of the methods referenced in FIG. 8 and FIG. 9 and respective paragraphs of the published application WO2020099438A1.

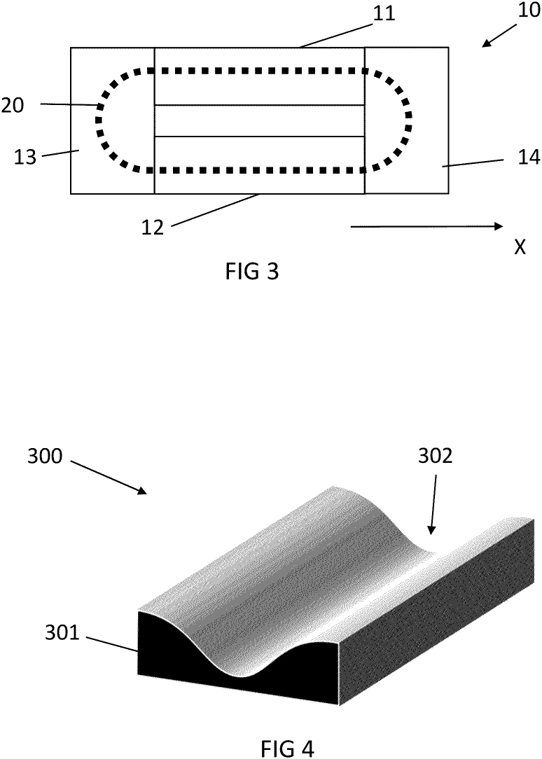

The target is preferably provided as a single piece which can be readily available for sputtering, with no need to assembly the pieces. The present invention is not limited thereto, and a target may comprise more than one piece. For example, FIG. 3 shows an exemplary embodiment where a planar target 10 is provided with four pieces 11, 12, 13, 14, following a racetrack shape 20. At least the central pieces, which are the longest (X-direction) are usually formed by many tiles, in existing targets. In contrast, in embodiments of the present invention each central piece 11, 12 may be manufactured as one single piece. They may cover more than half of the backing structure length.

The method of the present invention may be used to manufacture tubular targets or planar targets. The backing structure can be non-flat. For example, it may be concave. For example, it may be a bent plate. For example, it may be a mold or block with a groove for accumulating material, for providing material mainly on the zones where there is the most sputtering.

A detail of such backing structure is shown in FIG. 4. The structure 300 may be a block 301 with a groove 302, e.g. a smooth groove with sinusoidal or gaussian shape or the like. The direction of the groove 302 may be adapted to follow the racetrack when the block 301 is being used in as a backing structure of a target during sputtering process, as the relative position of the magnets with the block in the sputtering device determines the position of the racetrack and it can be predetermined. Spraying the backing structure 300 has the advantage that the material can be selectively provided on the structure 300. This means that the groove 302 may receive much more sprayed material than the areas at the sides of the groove 302.

FIG. 5 shows two schematic routes of thermal spraying and HIP on a concave backing structure. The top drawing 501 shows a cross section of the block 301 of FIG. 4. The leftmost middle drawing 502 shows target material 303 comprising volatile material, having been thermally sprayed on the block 301 thus forming a sprayed target product 401. In the embodiment shown in FIG. 5, the spraying of layers is not homogeneous by design. It is made so that the largest thickness of the sprayed layers of target material 303 is close or coincides with the deepest point of the groove. As the sprayed material comprises a substantial amount of volatile material (e.g. 60% or more) as explained in the first aspect of the present invention, the density is lower than the theoretical density, with high level or porosity. At this point, if the amount of surface pores is small (or after removing the open pores by post-processing, such as polishing), then the target product can be submitted to HIP. The target material densifies, e.g. up to 20% more dense with respect to the theoretical density; pores are removed from the sprayed material thus dense target material 304, the volume decreases and the profile 305 flattens, as shown in the leftmost lowest drawing 503. Thus, the target 402 has target material mainly on the area where the racetrack is generated (thus, in the zone of highest erosion). This allows a very efficient utilization of target material.

In some embodiments, an optional surface treatment, coating or capping layer 306 can be provided on the sprayed material 303 before submitting the target product to the HIP process, as shown in the rightmost top drawing 504. This coating of overlay material can be used to close any open pore in the material, for example by providing material on top so the open pores becomes closed, so there is no need to provide material with tailored viscosity and surface tension to fill the pores. As explained earlier with reference to the method steps of surface preparation 105 (FIG. 3), specifically of coating 107, this surface preparation may be done by spraying 108, for example cold or thermal spraying, or by other means compatible with the HIP processing, preferably safe methods that show no degassing. The coating provides a capping layer 306 has lower porosity than the underlying surface of the sprayed target, and with a homogeneous thickness, for example of a thickness of 1 mm or less, e.g. down to 100 microns. In some embodiments it is thicker than 0.5 mm. The overlay material may be a material different from the target material (e.g. metal), or it may comprise some of the materials of the target material, or it may be the same material but provided in a way in which density is optimized. The coated sprayed target product 403 can be submitted to HIP process as before, so the profile flattens thus providing dense target material layers 304, where target material is provided mainly on the erosion zone, as shown in the lowest rightmost drawing 505. If the overlay material is the same as the target material, the target 404 obtained after HIP process can be used to sputter. Otherwise, it is possible to perform a finishing step by removing the after-HIP capping layer 316 as explained earlier, thus obtaining a target 402 without overlay material. In case of tubular targets, the finishing step may comprise providing a cylindrical shape to the tubular target, e.g. by grinding or the like.

In a second aspect the present invention relates to a sputtering target. For example, the sputtering target may be provided in accordance with embodiments of the first aspect. The target is a single piece comprising ceramic material for sputtering. In some embodiments the absolute boiling or decomposition temperature of said material is less than 30% higher than its melting temperature, or it volatilizes or decomposes during or before melting. For example, it may have a sublimation temperature. The target has a material density of at least 90%, for example at least 95%, for example at least 98% of its theoretical density (or the density of the bulk material). In some embodiments, at least 40% in mass of the target material is a volatile ceramic, for example 50%, for example 60% or 70% in mass or more. The target material for sputtering is sprayed material, which subsequently is submitted to hot isostatic pressure together with the backing structure. Thus, the sputtering target includes a backing structure with sprayed and densified target material for sputtering on top thereof. This creates a bonding between the backing structure and the target material with interlinking structures from the roughness and mechanical locking, for example promoted by diffusion during spraying and the HIP process. This is clearly different from bonding by soldering or otherwise attaching a separate piece of densified target material to a backing structure. A solder layer of material with melting temperatures under 500° C. may not be present in embodiments of the present invention.

In some embodiments, one dimension of the target covers at least half, or more, for example all the backing structure. For example, one dimension of the target is at least 600 mm, for example at least 800 mm, or 1 m, 2 m, even 4 m. For example the side of a rectangular target, or the axis of a tubular target, may have these dimensions. The sputtering target may be a seamless target, made as a single piece without seams or the like. In some embodiments, it may be a target assembly where at least one, e.g. all the pieces, have a dimension of at least 600 mm, e.g. 800 mm, thus reducing the centers of arcing or dust formation. These targets can be used to sputter large substrates such as glass panes or the like. The method can also be used for refilling targets originally prepared by sintering, e.g. where the backing structure comprises smaller tiles.

The target may be preferably conductive, so sputtering at frequencies lower than RF can be provided. For example, it may include conductive material. For example, the target may have a resistivity of 1000 Ohm.cm or less, preferably below 100 Ohm.cm, more preferably below 10 Ohm.cm, even lower than 1 Ohm.cm. It is an advantage of embodiments of the present invention that the target presents a conductivity high enough so that it can be used with lower frequency AC sputtering process (e.g. below 200 kHz, such as 70 kHz or lower, e.g. 30 kHz or lower), or even DC sputtering process, suitable for providing optical coatings. The resistivity can be measured by any of the methods referenced in FIG. 8 and FIG. 9 and respective paragraphs of the published application WO2020099438A1.

In embodiments of the present invention, the backing structure may be a flat or curved plate, thus providing a planar target. In some embodiments the backing structure may be tubular, e.g. being cylindrical. It may comprise a conductive material (sufficiently conductive so sputtering is not hindered). For example, it may include stainless steel, which is inexpensive. It may comprise titanium, which presents good thermal and mechanical stability. It may also comprise copper, or aluminum or any metal or alloy with favorable electrical and thermal conductivity. It may comprise materials with similar composition or the same composition as the target material. For example, an old target can be used as backing structure, thus providing a target refill. The present invention is not limited by these examples. The target material can be provided directly on the backing structure, without adhesive layer, e.g. by thermal spraying of the target material on the backing structure.

In some embodiments, a bonding layer may be provided to improve adhesion of the sprayed target material. The thickness of the bonding layer, its mechanical and its thermal properties can be tailored to buffer differences between the backing structure and the deposited target material. In particular, the material may be chosen so its thermal expansion coefficient (TEC) may be between the TEC of the backing structure and the TEC of the sprayed target material. Thus, the adhesion of the target material and its integrity are less affected by shrinkage effects or temperature effects during the manufacturing process.

The optional bonding layer or bond coat may comprise bonding material which has a melting temperature of at least 500° C., for example at least 900° C. or above, for example 1000° C. or above, which may be provided on the backing structure before spraying the target material. The bonding material may be provided by spraying, also. If present, the thickness may be 500 microns or less, for example 300 microns or less, for example 250 microns, or 150 microns or less, for example around 100 microns. In some embodiments, the material may comprise titanium, nickel, nickel-aluminum alloys, copper, or a mixture thereof.

If present, the bonding material forms a layer between the backing structure and the densified material. In some cases, the material may diffuse between the backing structure and the material for sputtering, forming a composition gradient rather than a well defined layer.

FIG. 5 shows possible routes of providing planar targets where the backing structure is concave, thus providing a target in accordance with embodiments of the present invention.

In alternative embodiments, the backing structure may be convex, for example a tubular target, the present invention not being limited to cylindrical shapes. In this case, the present invention provides tubular targets. Optionally, as with the case of planar targets, the shape of the convex target may be thinner on the opposite extreme ends, where more erosion takes place. As before, spraying may be adapted so a larger amount of material is provided on the zones of larger erosion.

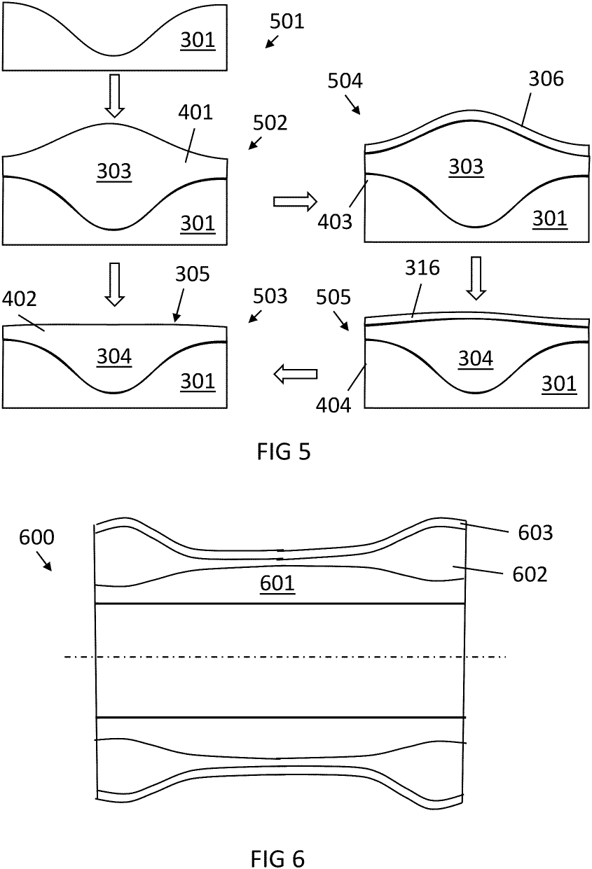

FIG. 6 shows a longitudinal cross section of a sprayed target product 600 with a tubular shape, comprising a hollow tubular backing structure 601 and sprayed layers of ceramic target material 602 covering the backing structure 601. In this and later figures, the central axis of the body is indicated by a dash-dot line. The hollow tubular backing structure may be molded, for example. In some embodiments of the present invention, the molded backing structure 601 is thinner at the ends, where a higher amount of material 602 has been sprayed on top. The sprayed target product 600 of FIG. 6 shows an optional capping layer 603 of dense overlay material for reducing or removing porosity from the surface of the target product, analogously to the coating 306 of planar targets.

The target product 600, obtained after spraying, can be submitted to HIP processing as described previously. The resulting target will be a tubular target, substantially cylindrical due to the increase of density with reduction of volume, especially at the ends where the mold presents molded grooves. The capping layer 603 after HIP can be removed if needed, as explained earlier. Another finishing step may be performed at the inside of the tubular backing structure 600 as to provide the desired inner diameter properties.

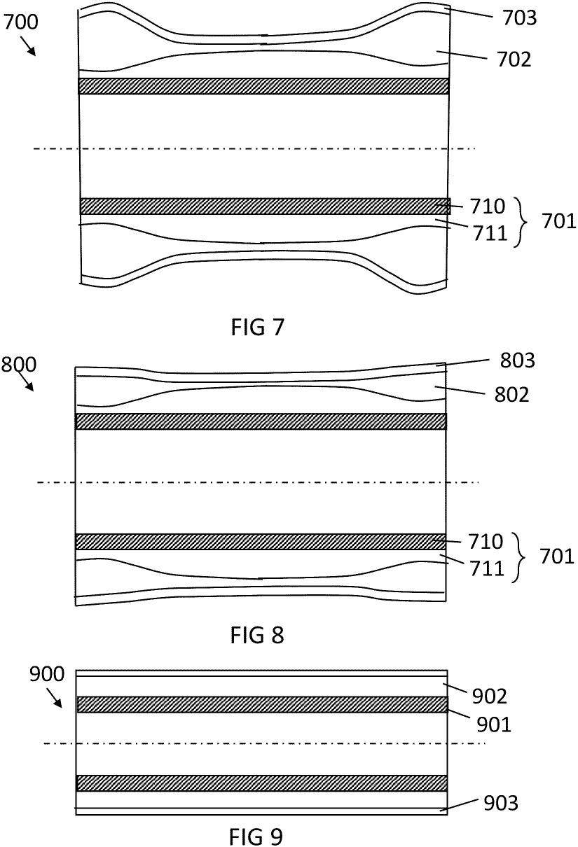

FIG. 7 shows a cross section of an alternative embodiment, where the sprayed target product 700 comprises sprayed material 702 provided on an eroded target 701 which needs to be refilled. This eroded target includes a carrier 710, which is a hollow tube, and eroded material 711 covering the carrier 710. As in the case of the molded backing structure 601, the ends are thinned, in this case due to the stronger erosion at the ends of the target due to the shape of the racetrack, during sputtering. The sprayed material is provided mainly over the eroded grooves, although a thinner layer may be sprayed over the rest of the material. Preferably, the sprayed target material 702 is the same material as the material 711 in the backing structure, covering the carrier 710. As before, an optional capping layer 703 may be provided to close open pores on the surface before the HIP process.

The resulting target 800 in accordance with embodiments of the present invention, after the HIP process, is shown in FIG. 8. The sprayed target material 702 is densified, the volume decreases and the profile flattens so a highly dense material 802 is provided around the backing structure 701. The surface becomes regular with a cylindrical profile, with constant or almost constant radius. Thus the tubular target may be a straight tube of cylindrical shape or a dogbone shape tubular target in accordance with the performance of the magnetron on which the target is planned to be used. As before, the capping layer 803 after HIP can be optionally removed.

A tubular target 900 in accordance with embodiments of the present invention is shown in FIG. 9, where the tubular target is a cylindrical target with a carrier tube being the backing structure 901. The target material 902 is provided homogeneously over the surface of the backing structure 901, by thermal spraying and subsequent HIP process. An optional capping layer 903 may be provided also.

It is noted that the method can be used to manufacture a target in accordance with embodiments of the second aspect of the present invention, for example to refill a target thereby providing a target of the second aspect.

1-19. (canceled)

20. A method of manufacturing a sputtering target comprising the step of providing a backing structure, providing target material comprising ceramic target material for spraying, subsequently thermal-spraying the target material over the backing structure, providing a target product where at least 40% in mass, of the target material comprises ceramic target material, and subsequently performing hot isostatic pressing on the target product thus increasing the density of the target material.

21. The method of the claim 20, wherein performing hot isostatic pressing comprises performing isostatic pressing without a canister.

22. The method of claim 20, wherein providing ceramic target material comprises providing volatile material
wherein the volatile material shows, at pressures between 700 hPa and 1300 hPa, either
a sublimation temperature, or
a melting temperature and an absolute boiling or decomposition temperature, the absolute boiling and/or decomposition temperature of said target volatile material being less than 30% higher, or being lower, than its melting temperature.

23. The method of claim 20, wherein the volatile material comprises at least 60% in mass, of the total target material.

24. The method of claim 20, wherein the ceramic material for sputtering comprises any of indium tin oxide, ZnO, or SnO2, or In2O3, or WO3 or any combination thereof.

25. The method of claim 20, wherein providing a sprayed target product comprises providing a target product with a density lower than 90%, of the theoretical density of the material, and
wherein performing hot isostatic pressing comprises increasing the target density by at least 5%, of its theoretical density, optionally obtaining an overall target material density of at least 95%, of its theoretical density.

26. The method of claim 20, wherein the method is adapted to provide a densified ceramic target material having a resistivity lower than 1000 Ohm.cm.

27. The method of claim 20, wherein providing a backing structure comprises providing a conductive mold including a groove adapted to overlap the sputter racetrack,
wherein thermal-spraying comprises thermal-spraying a large quantity of material at the areas within the groove and a small quantity on areas outside the groove, optionally
wherein providing a conductive mold including a groove comprises providing an eroded target,
wherein the method of manufacturing a sputtering target comprises refilling and recover the eroded target, optionally wherein providing a backing structure comprises providing a tubular backing structure.

28. The method of claim 20 further comprising coating the surface of the sprayed target with a capping layer of material with a lower porosity than the sprayed target before performing hot isostatic pressing, for removing surface pores.

29. The method of claim 20 further comprising coating the surface with a capping layer of material comprising or consisting of the same material as the sprayed target at higher density than the sprayed target.

30. The method of claim 28 wherein the capping layer is provided by spraying.

31. The method of claim 20 further comprising polishing the surface of the sprayed target before performing hot isostatic pressing.

32. The method of claim 20 further comprising partially or completely removing the outer layer of the target after performing hot isostatic pressing.

33. The method of claim 20 further comprising providing a bonding layer before spraying, wherein the bonding layer has a thickness of 500 micrometers or less.

34. The method of claim 33, wherein the bonding layer is provided by thermal spraying.

35. A sputtering target comprising a backing structure provided with a single piece comprising ceramic material for sputtering,
wherein, at pressures between 700 hPa and 1300 hPa, said material shows a sublimation temperature, or the absolute boiling or decomposition temperature of said material is less than 30% higher than its melting temperature or the material is decomposing before melting,
wherein the sputtering target comprises a bonding layer with a thickness of 0 µm to 500 µm between the backing structure and the target material, the target material having a material density of at least 95% of its theoretical density.

36. The target of claim 35, wherein the single piece has a length of at least 600 mm.

37. The target of claim 35, wherein the ceramic material for sputtering comprises any of indium tin oxide, ZnO, or SnO2, or In2O3, or WO3 or any combination thereof.

38. The target of claim 35 provided by the method of manufacturing a sputtering target comprising the step of providing a backing structure, providing target material comprising ceramic target material for spraying, subsequently thermal-spraying the target material over the backing structure, providing a target product where at least 40% in mass, of the target material comprises ceramic target material, and subsequently performing hot isostatic pressing on the target product thus increasing the density of the target material.
